(19) United States
(12) Patent Application Publication
(10) Pub. No.: US 2024/0213949 A1
(43) Pub. Date: Jun. 27, 2024

(54) ACOUSTIC WAVE DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 18/596,849

(22) Filed: Mar. 6, 2024

Related U.S. Application Data
(63) Continuation of application No. PCT/JP2022/035003, filed on Sep. 20, 2022.
(60) Provisional application No. 63/246,449, filed on Sep. 21, 2021.

(51) Int. Cl. H03H 9/02; H03H 9/13; H03H 9/17

(52) U.S. Cl. CPC H03H 9/02086; H03H 9/02031; H03H 9/02157; H03H 9/02228; H03H 9/132; H03H 9/173; H03H 9/175; H03H 9/176

(57) ABSTRACT

An acoustic wave device includes a support, a piezoelectric layer including lithium niobate or lithium tantalate, and an interdigital transducer electrode including busbars and electrode fingers. An acoustic reflection portion overlaps a portion of the IDT electrode. d/p is about 0.5 or less. An intersecting region includes a central region and edge regions. Gap regions are located between the intersecting region and the busbars. At least one mass addition film is provided in at least one of the edge regions or the gap regions, where any two points, in an electrode finger facing direction, of a portion in which the mass addition film is located are first and second points, thicknesses of the mass addition film at at least a pair of the first point and the second point are different from each other.

### CROSS REFERENCE TO RELATED APPLICATIONS

This application claims the benefit of priority to Provisional Application No. 63/246,449 filed on Sep. 21, 2021 and is a Continuation application of PCT Application No. PCT/JP2022/035003 filed on Sep. 20, 2022. The entire contents of each application are hereby incorporated herein by reference.

### BACKGROUND OF THE INVENTION

### 1. Field of the Invention

The present invention relates to acoustic wave devices.

### 2. Description of the Related Art

In the related art, an acoustic wave device has been widely used for a filter or the like of a mobile phone.

In recent years, as described in U.S. Pat. No. 10,491,192, an acoustic wave device using a bulk wave in a thickness shear mode has been proposed. In the acoustic wave device, a piezoelectric layer is provided on a support. A pair of electrodes are provided on the piezoelectric layer. The pair of electrodes face each other on the piezoelectric layer and are connected to different potentials. By applying an alternating-current (AC) voltage between the electrodes, the bulk wave in the thickness shear mode is excited.

In the acoustic wave device using the bulk wave in the thickness shear mode as described in U.S. Pat. No. 10,491,192, an unnecessary wave is generated at a frequency that is lower than a resonant frequency and is located near the resonant frequency. Therefore, there is a concern that electrical characteristics are deteriorated.

### SUMMARY OF THE INVENTION

Example embodiments of the present invention provide acoustic wave devices that are each able to reduce or prevent an unnecessary wave at a frequency that is lower than a resonant frequency and is located near the resonant frequency.

An example embodiment of the present invention provides an acoustic wave device including a support including a support substrate, a piezoelectric layer on the support and including lithium niobate or lithium tantalate, and an interdigital transducer (IDT) electrode on the piezoelectric layer and including a pair of busbars and a plurality of electrode fingers. An acoustic reflection portion is provided at a position overlapping at least a portion of the IDT electrode in plan view viewed in a laminating direction of the support and the piezoelectric layer. Where d is a thickness of the piezoelectric layer and p is a center-to-center distance between the electrode fingers adjacent to each other, d/p is about 0.5 or less. Some electrode fingers among the plurality of electrode fingers are connected to one of the pair of busbars of the IDT electrode, remaining electrode fingers among the plurality of electrode fingers are connected to another of the pair of busbars, and the electrode fingers connected to the one of the pair of busbars and the electrode fingers connected to the another of the pair of busbars are interdigitated with each other. Where a direction in which the adjacent electrode fingers face each other is an electrode finger facing direction, a region in which the adjacent electrode fingers overlap each other when viewed in the electrode finger facing direction is an intersecting region. Where a direction in which the plurality of electrode fingers extend is an electrode finger extending direction, the intersecting region includes a central region and a pair of edge regions sandwiching the central region in the electrode finger extending direction, a pair of gap regions are located between the intersecting region and the pair of busbars. At least one mass addition film is provided in at least one of the pair of edge regions or the pair of gap regions, and where any two points, in the electrode finger facing direction, of a portion in which the mass addition film is located are a first point and a second point, thicknesses of the mass addition film at at least a pair of the first point and the second point are different from each other.

According to example embodiments of the present invention, it is possible to provide acoustic wave devices that are each able to reduce or prevent an unnecessary wave at a frequency that is lower than a resonant frequency and is located near the resonant frequency.

The above and other elements, features, steps, characteristics and advantages of the present invention will become more apparent from the following detailed description of the example embodiments with reference to the attached drawings.

### BRIEF DESCRIPTION OF DRAWINGS

FIG. 1 is a schematic plan view of an acoustic wave device according to a first example embodiment of the present invention.

FIG. 2 is a schematic sectional view taken along line I-I in FIG. 1.

FIG. 3 is a diagram illustrating a relationship between a thickness of a mass addition film in an edge region and a gap region, and phase characteristics.

FIG. 4 is an enlarged view of FIG. 3 near 4000 MHz.

FIG. 5 is a sectional view illustrating a portion, which correspond to the cross section illustrated in FIG. 2, of an acoustic wave device according to a first modified example of the first example embodiment of the present invention.

FIG. 6 is a sectional view illustrating a portion, which correspond to the cross section illustrated in FIG. 2, of an acoustic wave device according to a second modified example of the first example embodiment of the present invention.

FIG. 7 is a plan view of an acoustic wave device according to a second example embodiment of the present invention.

FIG. 8 is a sectional view taken along line II-II in FIG. 7.

FIG. 9 is a plan view of an acoustic wave device according to a third example embodiment of the present invention.

FIG. 10 is a plan view of an acoustic wave device according to a fourth example embodiment of the present invention.

FIG. 11 is a sectional view taken along line I-I in FIG. 10.

FIG. 12 is a plan view of an acoustic wave device according to a fifth example embodiment of the present invention.

FIG. 13 is a sectional view taken along line I-I in FIG. 12.

FIG. 14 is a plan view of an acoustic wave device according to a sixth example embodiment of the present invention.

FIG. 15 is a sectional view taken along line I-I in FIG. 14.

FIG. 16A is a schematic perspective view illustrating an acoustic wave device using a bulk wave in a thickness shear mode, and FIG. 16B is a plan view illustrating an electrode structure on a piezoelectric layer.

FIG. 17 is a sectional view of a portion taken along line A-A in FIG. 16A.

FIG. 18A is a schematic elevational sectional view illustrating a Lamb wave that propagates through a piezoelectric film of the acoustic wave device, and FIG. 18B is a schematic elevational sectional view illustrating a bulk wave in a thickness shear mode that propagates through the piezoelectric film of the acoustic wave device.

FIG. 19 is a diagram illustrating an amplitude direction of the bulk wave in the thickness shear mode.

FIG. 20 is a diagram illustrating resonance characteristics of the acoustic wave device using the bulk wave in the thickness shear mode.

FIG. 21 is a diagram illustrating a relationship between d/p and a fractional bandwidth as a resonator in a case where p is a center-to-center distance between electrodes adjacent to each other and d is a thickness of a piezoelectric layer.

FIG. 22 is a plan view of an acoustic wave device using a bulk wave in a thickness shear mode.

FIG. 23 is a diagram illustrating resonance characteristics of an acoustic wave device of a reference example in which a spurious response appears.

FIG. 24 is a diagram illustrating a relationship between a fractional bandwidth and a phase rotation amount of an impedance of the spurious standardized at about 180 degrees as a magnitude of the spurious.

FIG. 25 is a diagram illustrating a relationship between d/2p and a metallization ratio MR.

FIG. 26 is a diagram illustrating a map of the fractional bandwidth with respect to Euler angles (0°, θ, ψ) of LiNbO₃ in a case where d/p is infinitely close to 0.

FIG. 27 is an elevational sectional view of an acoustic wave device including an acoustic multilayer film.

### DETAILED DESCRIPTION OF THE EXAMPLE EMBODIMENTS

Hereinafter, the present invention will be clarified by describing example embodiments of the present invention with reference to the accompanying drawings.

Each of example embodiments described in the present specification is merely an example, and partial replacement or combination of the configurations can be made between different example embodiments.

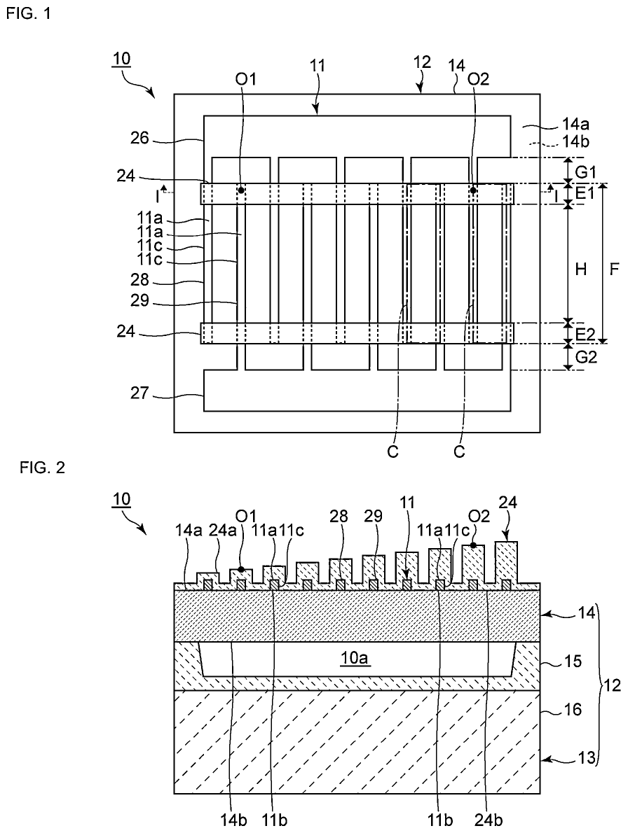

FIG. 1 is a schematic plan view of an acoustic wave device according to a first example embodiment of the present invention. FIG. 2 is a schematic sectional view taken along line I-I in FIG. 1.

As illustrated in FIG. 1, the acoustic wave device 10 includes a piezoelectric substrate interdigital transducer (IDT) electrode 11. As illustrated in FIG. 2, the piezoelectric substrate includes a 12 support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. The support 13 may include only the support substrate 16.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

As the material of the support substrate 16, for example, a semiconductor such as silicon, a ceramic such as aluminum oxide, or the like can be used. As the material of the insulating layer 15, for example, an appropriate dielectric such as silicon oxide or tantalum oxide can be used. The piezoelectric layer 14 is, for example, a lithium niobate layer such as a LiNbO₃ layer or a lithium tantalate layer such as a LiTaO₃ layer.

As illustrated in FIG. 2, a recess portion is provided in the insulating layer 15. The piezoelectric layer 14 is provided on the insulating layer 15 to close the recess portion. As a result, a hollow portion is provided. The hollow portion is a cavity portion 10a. In the present example embodiment, the support 13 and the piezoelectric layer 14 are disposed such that a portion of the support 13 and a portion of the piezoelectric layer 14 face each other with the cavity portion 10a interposed therebetween. The recess portion in the support 13 may be provided over the insulating layer 15 and the support substrate 16. Alternatively, the recess portion provided only in the support substrate 16 may be closed by the insulating layer 15. The recess portion may be provided in the piezoelectric layer 14. The cavity portion 10a may be a through hole provided in the support 13.

The IDT electrode 11 is provided on the first main surface 14a of the piezoelectric layer 14. The acoustic wave device 10 according to the present example embodiment is an acoustic wave resonator configured to use a bulk wave in a thickness shear mode. The acoustic wave device according to example embodiments of the present invention may be, for example, a filter device or a multiplexer having a plurality of acoustic wave resonators.

At least a portion of the IDT electrode 11 overlaps the cavity portion 10a of the support 13 in plan view. In the present specification, “in plan view” means viewing in a laminating direction of the support 13 and the piezoelectric layer 14, that is, in a direction from an upper side in FIG. 2. In FIG. 2, for example, the piezoelectric layer 14 side is an upper side of the support substrate 16 and the piezoelectric layer 14.

As illustrated in FIG. 1, the IDT electrode 11 includes a pair of busbars and a plurality of electrode fingers. Specifically, the pair of busbars include a first busbar 26 and a second busbar 27. The first busbar 26 and the second busbar 27 face each other. The plurality of electrode fingers are, specifically, a plurality of first electrode fingers 28 and a plurality of second electrode fingers 29. One end of each of the plurality of first electrode fingers 28 is connected to the first busbar 26. One end of each of the plurality of second electrode fingers 29 is connected to the second busbar 27. The plurality of first electrode fingers 28 and the plurality of second electrode fingers 29 are interdigitated with each other. The IDT electrode 11 may be made of a single metal film or a laminated metal film.

Hereinafter, the first electrode finger 28 and the second electrode finger 29 may be simply referred to as an electrode finger. The first busbar 26 and the second busbar 27 may be simply referred to as a busbar. In a case where a direction in which the plurality of electrode fingers extend is an electrode finger extending direction and a direction in which the electrode fingers adjacent to each other face each other is an electrode finger facing direction, the electrode finger extending direction and the electrode finger facing direction are orthogonal or substantially orthogonal to each other in the present example embodiment.

In the acoustic wave device 10, in a case where d is a thickness of the piezoelectric layer 14 and p is a center-to-center distance between the adjacent electrode fingers, d/p is, for example, about 0.5 or less. As a result, the bulk wave in the thickness shear mode is suitably excited.

The cavity portion 10a illustrated in FIG. 2 is an acoustic reflection portion. The acoustic reflection portion can effectively confine the energy of an acoustic wave to the piezoelectric layer 14 side. As the acoustic reflection portion, an acoustic reflection film such as, for example, an acoustic multilayer film described later may be provided.

Returning to FIG. 1, the IDT electrode 11 includes an intersecting region F. The intersecting region F is a region in which the adjacent electrode fingers overlap each other when viewed in the electrode finger facing direction. The intersecting region F includes a central region H and a pair of edge regions. The pair of edge regions are, specifically, a first edge region E1 and a second edge region E2. The first edge region E1 and the second edge region E2 face each other with the central region H interposed therebetween in the electrode finger extending direction. The first edge region E1 is located on the first busbar 26 side. The second edge region E2 is located on the second busbar 27 side.

The IDT electrode 11 includes a pair of gap regions. The pair of gap regions are located between the intersecting region F and the pair of busbars. The pair of gap regions are, specifically, a first gap region G1 and a second gap region G2. The first gap region G1 is located between the first busbar 26 and the first edge region E1. The second gap region G2 is located between the second busbar 27 and the second edge region E2.

One mass addition film 24 is provided in each of the first edge region E1 and the second edge region E2. Each mass addition film 24 has a strip shape. Each mass addition film 24 is provided on the first main surface 14a of the piezoelectric layer 14 to cover the plurality of electrode fingers.

More specifically, as illustrated in FIG. 2, each of the plurality of electrode fingers includes a first surface 11a, a second surface 11b, and a side surface 11c. The first surface 11a and the second surface 11b face each other. The side surface 11c is connected to the first surface 11a and the second surface 11b. Of the first surface 11a and the second surface 11b, the second surface 11b is a surface on the piezoelectric layer 14 side. The mass addition film 24 is provided on the first surface 11a of each electrode finger. The mass addition film 24 is continuously provided on the first surface 11a and in a region between the electrode fingers on the piezoelectric layer. The mass addition film 24 also covers the side surface 11c of each electrode finger.

The mass addition film 24 includes a third surface 24a and a fourth surface 24b. The third surface 24a and the fourth surface 24b face each other. Of the third surface 24a and the fourth surface 24b, the fourth surface 24b is a surface on the piezoelectric layer 14 side. A thickness of a portion, of the mass addition film 24, provided on the first surface 11a of the electrode finger is a distance between the first surface 11a of the electrode finger and the third surface 24a of the mass addition film. A thickness of a portion, of the mass addition film 24, provided in the region between the electrode fingers is a distance between the first main surface 14a of the piezoelectric layer 14 and the third surface 24a of the mass addition film 24.

The thicknesses of the portions of the mass addition film 24 provided on the first surfaces 11a of the electrode fingers are different from each other. Therefore, the thickness of the mass addition film 24 is not uniform. More specifically, in the present example embodiment, the thickness of the portion of the mass addition film 24 provided on the first surface 11a is increased from one side to the other side in the electrode finger facing direction. The same applies to the mass addition film 24 provided in the second edge region E2. The thickness of the mass addition film 24 not being uniform is not limited to the above example.

In the present example embodiment, the mass addition film 24 is provided only in both the edge regions. The mass addition film 24 may be provided in the gap regions. At least one mass addition film 24 need only be provided in at least either the edge regions or the gap regions.

Hereinafter, in the electrode finger facing direction, any two points of a portion in which the mass addition film 24 is located are referred to as a first point O1 and a second point O2. The first point O1 and the second point O2 illustrated in FIG. 1 or 2 are examples. A feature of the present example embodiment is that at least one mass addition film 24 is provided in at least either the edge regions or the gap regions, and the thicknesses of the mass addition films 24 at at least a set of the first point O1 and the second point O2 are different from each other. That is, in the present example embodiment, the thickness of the mass addition film 24 is not uniform in the electrode finger facing direction. As a result, it is possible to reduce or prevent an unnecessary wave at a frequency that is lower than a resonant frequency and is located near the resonant frequency. The details will be described later. In the following description, in a case where the unnecessary wave is simply described, unless otherwise specified, the unnecessary wave refers to the unnecessary wave that is generated at the frequency that is lower than the resonant frequency and is located near the resonant frequency.

As described above, in the first example embodiment, the thicknesses of the mass addition film 24 are different between portions provided on the first surfaces 11a of respective electrode fingers. Therefore, it is possible to disperse the frequency at which the unnecessary wave is generated, and it is possible to reduce the intensity of the unnecessary wave. Therefore, it is possible to reduce or prevent the unnecessary wave. The details of this advantageous effect will be described later with reference to a reference example.

The reference example is different from the first example embodiment in that a pair of mass addition films are provided over the pair of edge regions and the pair of gap regions, and the thicknesses of the pair of mass addition films are constant or substantially constant. Here, a plurality of acoustic wave devices of a plurality of reference examples in which the thicknesses of the mass addition films are different from each other are prepared. The phase characteristics of each prepared acoustic wave device are measured.

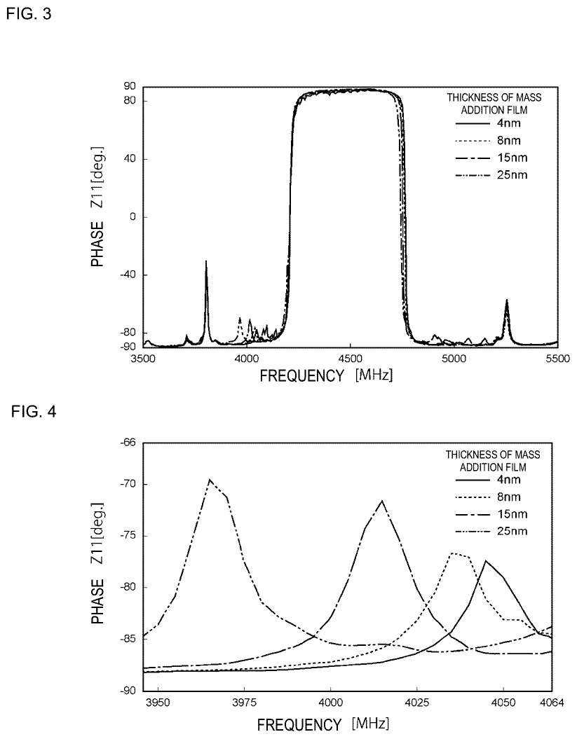

FIG. 3 is a diagram illustrating a relationship between the thickness of the mass addition film in the edge regions and the gap regions, and the phase characteristics. FIG. 4 is an enlarged view of FIG. 3 near 4000 MHZ.

As illustrated in FIGS. 3 and 4, it can be seen that the frequencies at which ripples caused by the unnecessary waves occur are different in a case where the thicknesses of the mass addition films are different. The same applies to a case where the mass addition film is provided only in the edge regions as in the first example embodiment. Further, the same applies to a case where the mass addition film is provided only in the gap regions. As illustrated in FIG. 1, in the first example embodiment, one mass addition film 24 includes two or more portions having different thicknesses from each other in the electrode finger facing direction. More specifically, in the first example embodiment, the thicknesses of the mass addition film 24 are different between respective portions provided on the first electrode fingers 28 or the second electrode fingers 29 provided on the first surface 11a. As a result, it is possible to disperse the frequency at which the unnecessary wave is generated, and it is possible to reduce the intensity of the unnecessary wave. Therefore, it is possible to reduce or prevent the unnecessary wave.

As illustrated in FIG. 1, the intersecting region F in the IDT electrode 11 of the acoustic wave device 10 includes a plurality of excitation regions C. More specifically, the excitation region C is a region between the centers of the adjacent electrode fingers. By applying an alternating-current (AC) voltage to the IDT electrode 11, the acoustic waves are excited in the plurality of excitation regions C. On the other hand, in the acoustic wave device using a surface acoustic wave, the intersecting region is one excitation region.

Unlike the acoustic wave device using the surface acoustic wave, the acoustic wave device 10 using the bulk wave in the thickness shear mode has the same or substantially the same configuration as a configuration in which a plurality of resonators each including the excitation region C are connected in parallel. Therefore, in the acoustic wave device 10, even in a case where the thickness of the mass addition film 24 is not uniform in the electrode finger facing direction, the waveforms of the frequency characteristics such as the phase characteristics are less likely to be disturbed. Therefore, in the first example embodiment, it is possible to reduce or prevent the unnecessary wave without the electrical characteristics being deteriorated.

Further, by providing the mass addition film 24 only in the edge regions, an amount of change in the fractional bandwidth can be reduced. As a result, it is possible to stabilize the electrical characteristics of the acoustic wave device 10.

In the first example embodiment, the mass addition film 24 is provided, and thus a low acoustic velocity region is provided in each edge region. The low acoustic velocity region is a region in which the acoustic velocity is lower than the acoustic velocity in the central region H. In the electrode finger extending direction, the central region H and the low acoustic velocity region are disposed in this order from an inner side portion to an outer side portion of the IDT electrode 11. As a result, a piston mode is provided, and a transverse mode can be reduced or prevented.

The acoustic wave device according to the present example embodiment uses the bulk wave in the thickness shear mode instead of the surface acoustic wave. In this case, even in a case where the mass addition film 24 is provided in each gap region, the piston mode can be suitably provided.

It is preferable to use, as the material of the mass addition film 24, at least one dielectric selected from, for example, silicon oxide, tungsten oxide, niobium oxide, tantalum oxide, and hafnium oxide. In this case, the piston mode can be more reliably provided, and the transverse mode can be more reliably reduced or prevented.

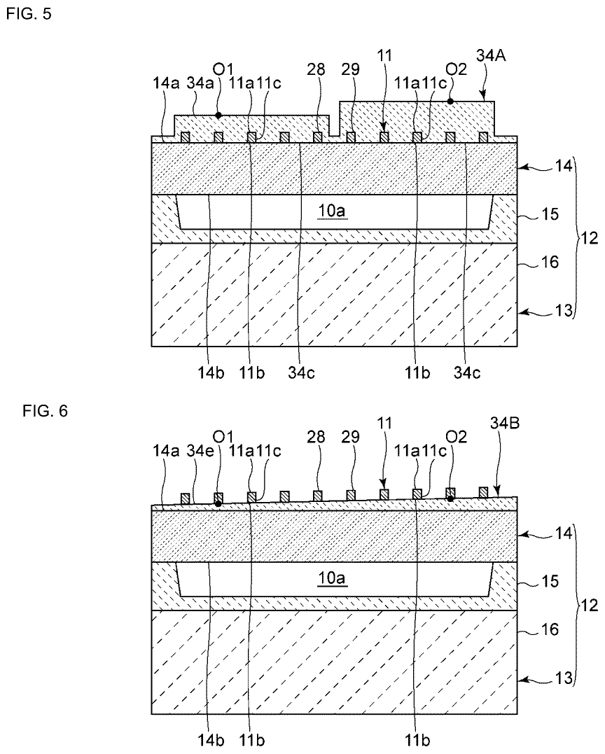

In the first example embodiment, the thicknesses of the respective portions of the mass addition film 24 located on the adjacent electrode fingers are different from each other. The present invention is not limited thereto. For example, in a first modified example of the first example embodiment illustrated in FIG. 5, a mass addition film 34A includes a plurality of flat portions 34c. In each flat portion 34c, a third surface 34a is flat. Therefore, in each flat portion 34c, a distance between the first main surface 14a of the piezoelectric layer 14 and the third surface 34a of the mass addition film 34A is constant or substantially constant. In addition, in each flat portion 34c, the thicknesses of the respective portions, of the mass addition film 34A, provided on the first surfaces 11a of the adjacent electrode fingers are the same or substantially the same. On the other hand, the thicknesses of the respective portions, of the mass addition film 34A, provided on the first surfaces 11a of the electrode fingers are different from each other between the plurality of flat portions 34c. Also in this case, it is possible to disperse the frequency at which the unnecessary wave is generated, and it is possible to reduce or prevent the unnecessary wave.

Returning to FIG. 2, in the first example embodiment, in a portion in which the mass addition film 24 and the electrode finger are laminated, the electrode finger and the mass addition film 24 are laminated in this order from the piezoelectric layer 14 side. That is, in the portion in which the mass addition film 24 and the electrode finger are laminated, the mass addition film 24 is provided on the first surface 11a of the electrode finger. The order of laminating the mass addition film 24 and the electrode finger is not limited to the above example. In a second modified example of the first example embodiment illustrated in FIG. 6, in a portion in which a mass addition film 34B and the electrode finger are laminated, the mass addition film 34B and the electrode finger are laminated in this order from the piezoelectric layer 14 side. That is, the mass addition film 34B is provided between the second surfaces 11b of the plurality of electrode fingers and the piezoelectric layer 14.

In the present modified example, a third surface 34e of the mass addition film 34B is inclined. More specifically, the thickness of the mass addition film 34B is increased from one side to the other side in the electrode finger facing direction. As a result, also in the present modification, it is possible to disperse the frequency at which the unnecessary wave is generated, and it is possible to reduce or prevent the unnecessary wave.

The configuration in which the mass addition film 34A includes the flat portion 34c in the first modified example illustrated in FIG. 5 can also be applied to a configuration other than the first modified example. Similarly, the configuration in which the mass addition film 34B is provided between the second surfaces 11b of the plurality of electrode fingers and the piezoelectric layer 14 in the second modified example illustrated in FIG. 6 can be applied to a configuration other than the second modified example.

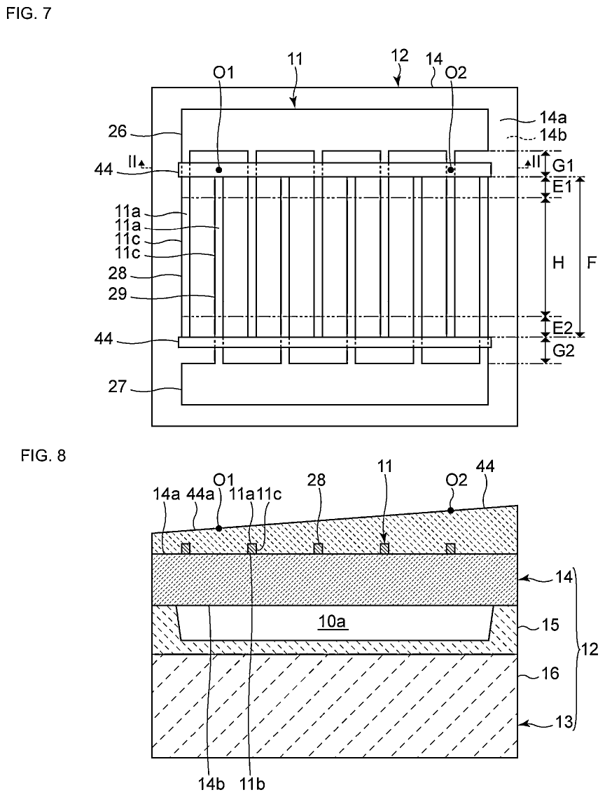

FIG. 7 is a plan view of an acoustic wave device according to a second example embodiment of the present invention. FIG. 8 is a sectional view taken along line II-II in FIG. 7.

As illustrated in FIGS. 7 and 8, the present example embodiment is different from the first example embodiment in that the mass addition film 44 is provided only in both the gap regions, and in the shape of the mass addition film 44. Except for the above points, the acoustic wave device according to the present example embodiment has the same or substantially the same configurations as the acoustic wave device 10 according to the first example embodiment.

As illustrated in FIG. 7, one of the pair of mass addition films 44 is provided in the first gap region G1. The other of the pair of mass addition films 44 is provided in the second gap region G2. The mass addition film 44 does not extend to an end portion on the busbar side in the gap region. The mass addition film 44 may be provided in the entirety or substantially the entirety of the gap region. The mass addition film 44 need only be provided in at least a portion of the gap region in the electrode finger extending direction.

As illustrated in FIG. 8, the third surface 44a of the mass addition film 44 is inclined. The thickness of the mass addition film 44 is increased from one side to the other side in the electrode finger facing direction. As described above, the thickness of the mass addition film 44 is not uniform in the electrode finger facing direction. As a result, as in the first example embodiment, it is possible to disperse the frequency at which the unnecessary wave is generated, and it is possible to reduce or prevent the unnecessary wave.

The thickness of the mass addition film 44 is continuously changed to be increased from one side to the other side in the electrode finger facing direction. For example, the thickness of the mass addition film 44 may be changed to be thick and then changed to be thin from one side to the other side in the electrode finger facing direction.

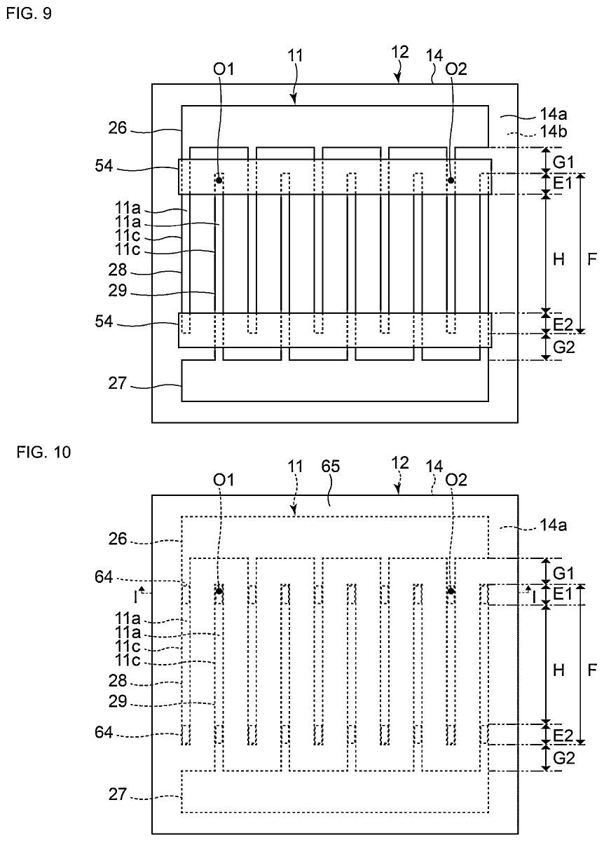

FIG. 9 is a plan view of an acoustic wave device according to a third example embodiment of the present invention.

The present example embodiment is different from the first example embodiment in that the mass addition film 54 is provided over the edge regions and the gap regions, and in the shape of the mass addition film 54. Except for the above points, the acoustic wave device according to the present example embodiment has the same or substantially the same configurations as the acoustic wave device 10 according to the first example embodiment.

One of the pair of mass addition films 54 is provided over the first edge region E1 and the first gap region G1. The other of the pair of mass addition films 54 is provided over the second edge region E2 and the second gap region G2. In the present example embodiment, the thickness of the mass addition film 54 is not uniform in the electrode finger facing direction. As a result, as in the first example embodiment, it is possible to disperse the frequency at which the unnecessary wave is generated, and it is possible to reduce or prevent the unnecessary wave.

In the first to third example embodiments described above, the mass addition film has a strip shape. For example, in the first example embodiment illustrated in FIG. 1, the mass addition film 24 is continuously provided on the plurality of electrode fingers and in the region between the electrode fingers. The mass addition film may be provided only on the electrode fingers, for example. This example is described with reference to a fourth example embodiment of the present invention.

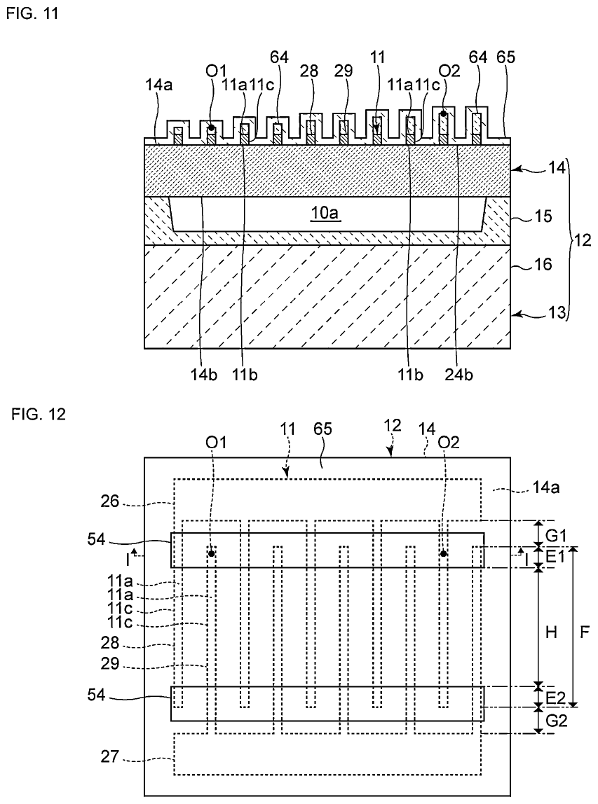

FIG. 10 is a plan view of an acoustic wave device according to the fourth example embodiment. FIG. 11 is a sectional view taken along line I-I in FIG. 10.

As illustrated FIG. 10, the present example embodiment is different from the first example embodiment in that a protective film 65 is provided on the first main surface 14a of the piezoelectric layer 14 to cover the IDT electrode 11 and that a plurality of mass addition films 64 are provided in each edge region. Except for the above points, the acoustic wave device according to the present example embodiment has the same or substantially the same configurations as the acoustic wave device 10 according to the first example embodiment. The protective film 65 does not have to be provided.

The plurality of mass addition films 64 are arranged in the electrode finger facing direction. In plan view, each mass addition film 64 and each electrode finger overlap each other. More specifically, in the first edge region E1, each mass addition film 64 is provided only on the first surface 11a of one first electrode finger 28 or only on the first surface 11a of one second electrode finger 29. The same applies to the second edge region E2. As described above, the plurality of mass addition films 64 are provided only in the regions overlapping the electrode fingers in plan view.

As illustrated in FIG. 11, in the present example embodiment, in a portion in which the electrode finger, the mass addition film 64, and the protective film 65 are laminated, the electrode finger, the mass addition film 64, and the protective film 65 are laminated in this order. The order of the lamination is not limited to the above example.

The thicknesses of the mass addition films 64 provided in the first edge regions E1 are different from each other. Specifically, the thickness of the mass addition film 64 is increased for every other thickness from one side to the other side in the electrode finger facing direction. More specifically, among three mass addition films 64 provided side by side in the electrode finger facing direction, the lengths of the two adjacent mass addition films 64 are the same, and the lengths of the two mass addition films 64 and the length of the remaining one mass addition film 64 are different from each other. In this way, the thickness of the mass addition film 64 is periodically changed.

As described above, the thicknesses of the plurality of mass addition films 64 are not uniform in the electrode finger facing direction. The same applies to the second edge region E2. As a result, as in the first example embodiment, it is possible to disperse the frequency at which the unnecessary wave is generated, and it is possible to reduce or prevent the unnecessary wave.

In each of the edge regions, the thicknesses of at least two mass addition films 64 of the plurality of mass addition films 64 need only be different from each other. In this case, the thicknesses of the mass addition films 64 at at least a set of the first point O1 and the second point O2 are different from each other. As a result, the unnecessary wave can be reduced or prevented.

Each mass addition film 64 is not in contact with both electrode fingers connected to the potentials different from each other. In this case, metal can be used as the material of the plurality of mass addition films 64. A dielectric may be used as the material of the plurality of mass addition films 64.

As in the first example embodiment, the plurality of mass addition films 64 are provided only in both of the edge regions. As a result, also in the present example embodiment, the amount of change in the fractional bandwidth can be reduced, and the electrical characteristics of the acoustic wave device can be stabilized. The plurality of mass addition films 64 may be provided over the first edge region E1 and the first gap region G1 illustrated in FIG. 10. Similarly, the plurality of mass addition films 64 may be provided over the second edge region E2 and the second gap region G2. Alternatively, the plurality of mass addition films 64 may be provided only in both the gap regions.

In the present example embodiment, the protective film 65 is provided. As a result, the IDT electrodes 11 are less likely to be damaged. As the material of the protective film 65, for example, silicon oxide, silicon nitride, silicon oxynitride, or the like can be used. The configuration in which the protective film 65 is provided can also be used in a configuration other than the present example embodiment.

In a case where the materials of the protective film 65 and the mass addition film 64 are the same, the thickness of the protective film 65 is the thickness of the protective film 65 in the central region H illustrated in FIG. 10. The thickness of the mass addition film 64 is obtained by subtracting the thickness of the protective film 65 from the total thickness of the protective film 65 and the mass addition film 64.

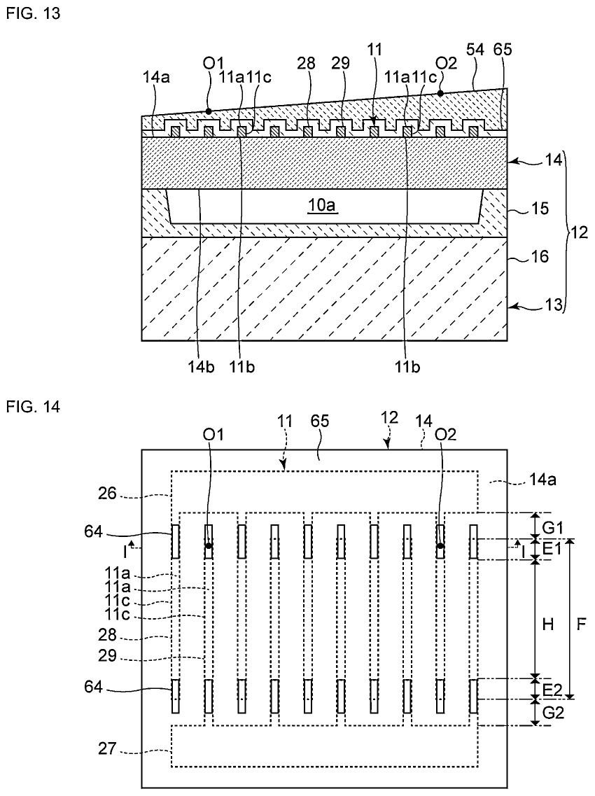

FIG. 12 is a plan view of an acoustic wave device according to a fifth example embodiment of the present invention. FIG. 13 is a sectional view taken along line I-I in FIG. 12.

As illustrated in FIG. 12, the present example embodiment is different from the third example embodiment in that the protective film 65 is provided and the mass addition film 54 is provided on the protective film 65. Except for the above points, the acoustic wave device according to the present example embodiment has the same or substantially the same configurations as the acoustic wave device according to the third example embodiment.

As in the third example embodiment, one of the pair of mass addition films 54 is provided over the first edge region E1 and the first gap region G1. The other of the pair of mass addition films 54 is provided over the second edge region E2 and the second gap region G2. Each mass addition film 54 is continuously provided in a region overlapping the plurality of electrode fingers and overlapping the region between the electrode fingers in plan view.

As illustrated in FIG. 13, the mass addition film 54 is indirectly provided on the plurality of electrode fingers with the protective film 65 interposed therebetween. The mass addition film 54 is continuously provided on the plurality of electrode fingers and in the region between the electrode fingers. In addition, the thickness of the mass addition film 54 is increased from one side to the other side in the electrode finger facing direction. As described above, the thickness of the mass addition film 54 is not uniform in the electrode finger facing direction. As a result, as in the third example embodiment, it is possible to disperse the frequency at which the unnecessary wave is generated, and it is possible to reduce or prevent the unnecessary wave.

In the present example embodiment, the mass addition film 54 is not in contact with the electrode fingers. In this case, metal can be used as the material of the mass addition film 54. Here, the mass addition film 54 faces the plurality of electrode fingers with the protective film 65 interposed therebetween. Therefore, in a case where metal is used as the material of the mass addition film 54, the electrostatic capacity of the acoustic wave device can be increased. Therefore, an area of the IDT electrode 11 can be reduced to obtain a desired electrostatic capacity. Therefore, the size of the acoustic wave device can be reduced. A dielectric may be used as the material of the mass addition film 54.

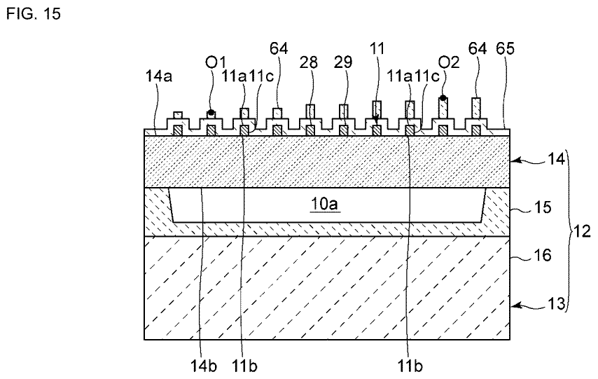

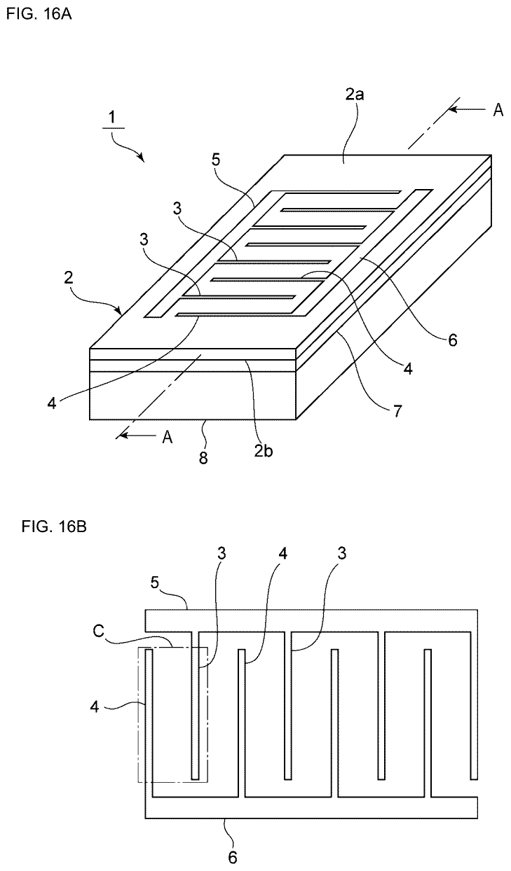

FIG. 14 is a plan view of an acoustic wave device according to a sixth example embodiment of the present invention. FIG. 15 is a sectional view taken along line I-I in FIG. 14.

As illustrated in FIG. 14, the present example embodiment is different from the fifth example embodiment in that the plurality of mass addition films 64 are provided. Except for the above points, the acoustic wave device according to the present example embodiment has the same substantially the same configurations as the acoustic wave device according to the fifth example embodiment.

The plurality of mass addition films 64 are provided on the protective film 65. Among all of the mass addition films 64, some mass addition films 64 are provided over the first edge region E1 and the first gap region G1, and some other mass addition films 64 are provided over the second edge region E2 and the second gap region G2.

As illustrated in FIG. 15, the thickness of the mass addition film 64 is periodically increased from one side to the other side in the electrode finger facing direction. As described above, also in the present example embodiment, the thickness of the mass addition film 64 is not uniform in the electrode finger facing direction. As a result, as in the fifth example embodiment, it is possible to disperse the frequency at which the unnecessary wave is generated, and it is possible to reduce or prevent the unnecessary wave.

Hereinafter, the details of the thickness shear mode will be described. The “electrode” in the IDT electrode described later corresponds to an electrode finger. The support in the following example corresponds to a support substrate. Hereinafter, a case where a certain member is made of a certain material includes a case where a small amount of an impurity is included to such an extent that the electrical characteristics of the acoustic wave device are not significantly deteriorated.

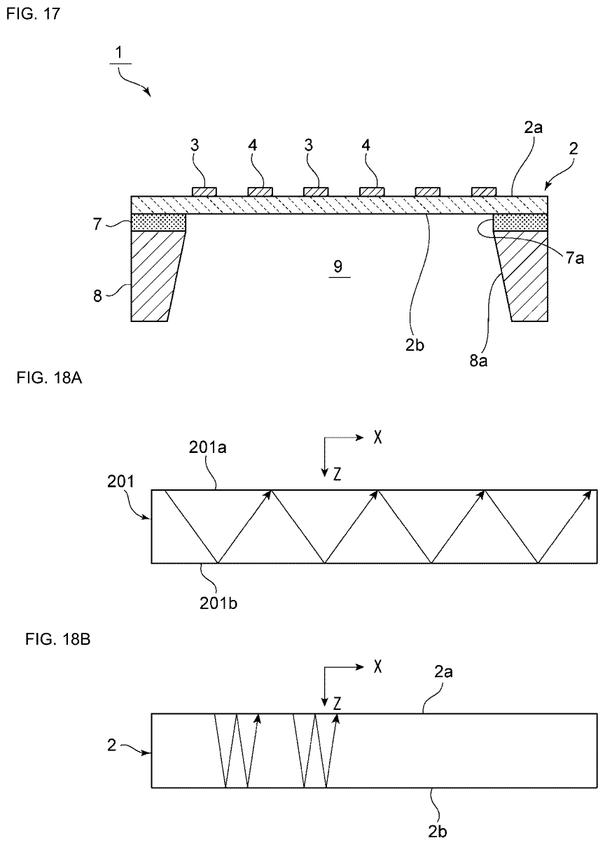

FIG. 16A is a schematic perspective view illustrating an acoustic wave device using the bulk wave in the thickness shear mode, and FIG. 16B is a plan view illustrating the electrode structure on the piezoelectric layer, and FIG. 17 is a sectional view of a portion taken along line A-A in FIG. 16A.

An acoustic wave device 1 includes a piezoelectric layer 2 made of, for example, LiNbO₃. The piezoelectric layer 2 may be made of, for example, LiTaO₃. A cut-angle of LiNbO₃ or LiTaO₃ is a Z cut, but may be a rotated Y cut or an X cut. The thickness of the piezoelectric layer 2 is not particularly limited, but is preferably, for example, about 40 nm or more and about 1000 nm or less, and more preferably, for example, about 50 nm or more and about 1000 nm or less in order to effectively excite the thickness shear mode. The piezoelectric layer 2 includes first and second main surfaces 2a and 2b facing each other. Electrodes 3 and 4 are provided on the first main surface 2a. Here, the electrode 3 is an example of a “first electrode” and the electrode 4 is an example of a “second electrode”. In FIGS. 16A and 16B, the plurality of electrodes 3 are a plurality of first electrode fingers connected to a first busbar 5. The plurality of electrodes 4 are a plurality of second electrode fingers connected to a second busbar 6. The plurality of electrodes 3 and the plurality of electrodes 4 are interdigitated with each other. Each of the electrodes 3 and 4 has a rectangular or substantially rectangular shape and a length direction. The electrode 3 and the electrode 4 adjacent thereto face each other in a direction orthogonal or substantially orthogonal to the length direction. Both of the length direction of the electrodes 3 and 4 and the direction orthogonal or substantially orthogonal to the length direction of the electrodes 3 and 4 are directions intersecting a thickness direction of the piezoelectric layer 2. Therefore, it can be said that the electrode 3 and the electrode 4 adjacent thereto face each other in the direction intersecting the thickness direction of the piezoelectric layer 2. In addition, the length direction of the electrodes 3 and 4 may be interchanged with the direction orthogonal or substantially orthogonal to the length direction of the electrodes 3 and 4 illustrated in FIGS. 16A and 16B. That is, in FIGS. 16A and 16B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 16A and 16B. A plurality of pairs each including a structure in which the electrode 3 connected to one potential and the electrode 4 connected to the other potential are adjacent to each other are provided in a direction orthogonal or substantially orthogonal to the length direction of the electrodes 3 and 4. Here, a case where the electrodes 3 and 4 are adjacent to each other does not mean a case where the electrodes 3 and 4 are disposed to be in direct contact with each other, but means a case where the electrodes 3 and 4 are disposed with a gap therebetween. In a case where the electrodes 3 and 4 are adjacent to each other, electrodes connected to a hot electrode or a ground electrode, including other electrodes 3 and 4, are not disposed between the electrodes 3 and 4 adjacent to each other. The number of pairs does not have to be integer pairs, but may be 1.5 pairs, 2.5 pairs, or the like. The center-to-center distance, that is, the pitch between the electrodes 3 and 4 is preferably in a range of, for example, about 1 μm or more and about 10 μm or less. The widths of the electrodes 3 and 4, that is, the dimensions of the electrodes 3 and 4 in the facing direction are preferably in a range of, for example, about 50 nm or more and about 1000 nm or less, and more preferably in a range of about 150 nm or more and about 1000 nm or less. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal to a polarization direction of the piezoelectric layer 2. This is not a case when a piezoelectric material with a different cut-angle is used as the piezoelectric layer 2. Here, “orthogonal” is not limited to being strictly orthogonal, but may be substantially orthogonal (angle between the direction orthogonal to the length direction of the electrodes 3 and 4 and the polarization direction is, for example, in a range of about 90°±10°).

A support 8 is laminated on the second main surface 2b side of the piezoelectric layer 2 with an insulating layer 7 interposed therebetween. The insulating layer 7 and the support 8 have a frame shape and include through holes 7a and 8a as illustrated in FIG. 17. As a result, a cavity portion 9 is provided. The cavity portion 9 is provided not to disturb the vibration of the excitation region C of the piezoelectric layer 2. Therefore, the support 8 is laminated on the second main surface 2b with the insulating layer 7 interposed therebetween at a position not overlapping the portion in which at least a pair of electrodes 3 and 4 are provided. It should be noted that the insulating layer 7 does not have to be provided. Therefore, the support 8 can be directly or indirectly laminated on the second main surface 2b of the piezoelectric layer 2.

The insulating layer 7 is made of, for example, silicon oxide. In addition to silicon oxide, an appropriate insulating material such as, for example, silicon oxynitride or alumina can be used. The support 8 is made of, for example, Si. A plane orientation of the plane of Si on the piezoelectric layer 2 side may be (100), (110), or (111). Si included in the support 8 is preferably high resistance having a resistivity of, for example, about 4 kΩcm or more. The support 8 can also be made of an appropriate insulating material or semiconductor material.

Examples of the material of the support 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 are made of appropriate metals or alloys, such as, for example, Al and AlCu alloys. In the present example embodiment, the electrodes 3 and 4 and the first and second busbars 5 and 6 include an Al film laminated on a Ti film. An adhesion layer other than the Ti film may be used.

The AC voltage for driving is applied between the plurality of electrodes 3 and the plurality of electrodes 4. More specifically, the AC voltage is applied between the first busbar 5 and the second busbar 6. As a result, it is possible to obtain the resonance characteristics using the bulk wave in the thickness shear mode excited in the piezoelectric layer 2. In the acoustic wave device 1, in a case where d is the thickness of the piezoelectric layer 2 and p is the center-to-center distance between any adjacent electrodes 3 and 4 among the plurality of pairs of electrodes 3 and 4, d/p is, for example, about 0.5 or less. As a result, the bulk wave in the thickness shear mode is effectively excited, and good resonance characteristics can be obtained. More preferably, for example, d/p is about 0.24 or less, and in this case, further improved resonance characteristics can be obtained.

In the acoustic wave device 1, since the above-described configuration is provided, even in a case where the number of pairs of the electrodes 3 and 4 is reduced in order to reduce the size, a Q value is less likely to be decreased. This is because the propagation loss is small even in a case where the number of electrode fingers in the reflectors on both sides is small. In addition, the number of electrode fingers can be reduced because the bulk wave in the thickness shear mode is used. A difference between the Lamb wave used in the acoustic wave device and the bulk wave in the thickness shear mode will be described with reference to FIGS. 18A and 18B.

FIG. 18A is a schematic elevational sectional view illustrating the Lamb wave that propagates through the piezoelectric film of the acoustic wave device as described in Japanese Unexamined Patent Application Publication No. 2012-257019. Here, the wave propagates in a piezoelectric film 201 as indicated by an arrow. Here, in the piezoelectric film 201, a first main surface 201a and a second main surface 201b face each other, and a thickness direction connecting the first main surface 201a and the second main surface 201b is a Z direction. An X direction is a direction in which the electrode fingers of the IDT electrodes are arranged. As illustrated in FIG. 18A, in the Lamb wave, the wave propagates in the X direction as illustrated in the figure. Since the wave is a plate wave, although the piezoelectric film 201 vibrates as a whole, the wave propagates in the X direction, and thus the reflectors are disposed on both sides to obtain the resonance characteristics. Therefore, the propagation loss of the wave occurs, and the Q value is decreased in a case where the size reduction is attempted, that is, in a case where the number of pairs of the electrode fingers is decreased.

On the other hand, as illustrated in FIG. 18B, in the acoustic wave device 1, since the vibration displacement is a thickness shear direction, the wave propagates and resonates in the direction connecting the first main surface 2a and the second main surface 2b of the piezoelectric layer 2, that is, the Z direction. That is, an X-direction component of the wave is significantly smaller than a Z-direction component. In addition, since the resonance characteristics are obtained by the propagation of the wave in the Z direction, the propagation loss is less likely to occur even when the number of the electrode fingers of the reflector is reduced. Therefore, even in a case where the number of pairs each including the electrodes 3 and 4 is reduced when the size reduction is attempted, the Q value is less likely to be decreased.

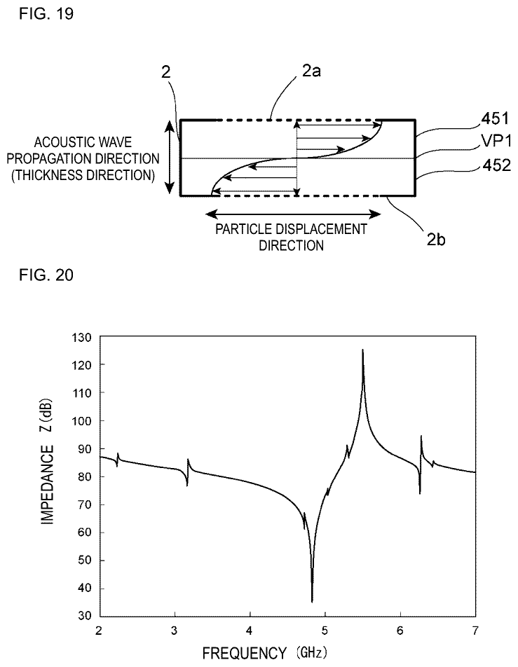

Amplitude directions of the bulk waves of the thickness shear mode are opposite to each other between a first region 451 included in the excitation region C of the piezoelectric layer 2 and a second region 452 included in the excitation region C, as illustrated in FIG. 19. FIG. 19 schematically illustrates the bulk waves when the voltage is applied between the electrodes 3 and 4 such that the potential of the electrode 4 is higher than the potential of the electrode 3. The first region 451 is a region of the excitation region C between a virtual plane VP1, which is orthogonal or substantially orthogonal to the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least a pair of electrodes including the electrodes 3 and 4 are disposed, the waves are not intended to propagate in the X direction, and thus the number of pairs of the electrode pair including the electrodes 3 and 4 does not have to be two or more. That is, at least one pair of electrodes need only be provided.

For example, the electrode 3 is an electrode connected to a hot potential and the electrode 4 is an electrode connected to a ground potential. The electrode 3 may be connected to the ground potential and the electrode 4 may be connected to the hot potential. In the present example embodiment, at least a pair of electrodes include the electrodes connected to the hot potential or the electrodes connected to the ground potential, as described above, and no floating electrodes are provided.

FIG. 20 is a diagram illustrating the resonance characteristics of the acoustic wave device illustrated in FIG. 17. The design parameters of the acoustic wave device 1 with the resonance characteristics are as follows.

Piezoelectric layer 2: LiNbO₃ with Euler angles (0°, 0°, 90°), thickness=about 400 nm.

When viewed in the direction orthogonal or substantially orthogonal to the length direction of the electrodes 3 and 4, the length of the region in which the electrodes 3 and 4 overlap each other, that is, the length of the excitation region C=about 40 μm, the number of pairs of the electrodes including the electrodes 3 and 4=21 pairs, the center-to-center distance between the electrodes=about 3 μm, the width of the electrodes 3 and 4=about 500 nm, and d/p=about 0.133.

Insulating layer 7: silicon oxide film having a thickness of about 1 μm.

Support 8: Si.

The length of the excitation region C is the dimension of the excitation region C in the length direction of the electrodes 3 and 4.

In the present example embodiment, the electrode-to-electrode distances in the electrode pairs each including the electrodes 3 and 4 are all equal or substantially equal in the plurality of pairs. That is, the electrodes 3 and 4 are disposed at equal or substantially equal pitches.

As is clear from FIG. 20, good resonance characteristics with the fractional bandwidth of about 12.5% are obtained regardless of excluding reflectors.

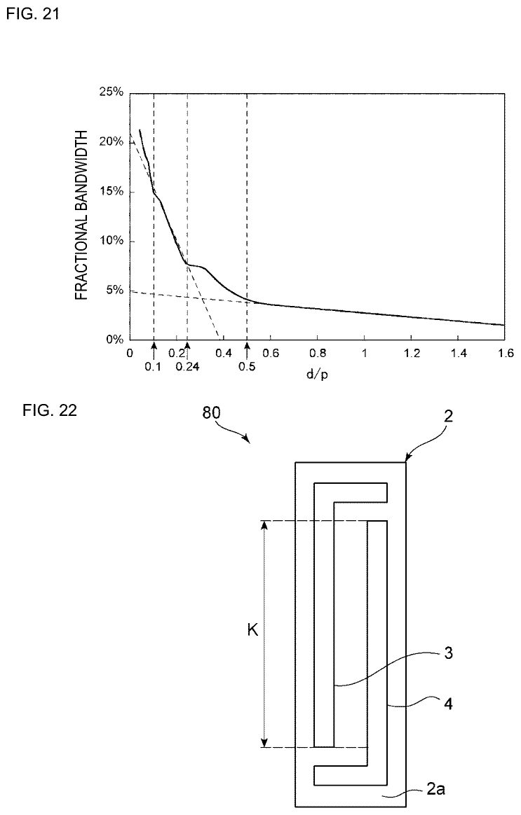

In a case where d is the thickness of the piezoelectric layer 2 and p is the center-to-center distance between the electrodes 3 and 4, in the present example embodiment, as described above, d/p is, for example, about 0.5 or less, more preferably about 0.24 or less. This will be described with reference to FIG. 21.

A plurality of acoustic wave devices are obtained similarly, but with different d/p, to the acoustic wave device that obtains the resonance characteristics illustrated in FIG. 20. FIG. 21 is a diagram illustrating a relationship between d/p and the fractional bandwidth as the resonator of the acoustic wave device.

As is clear from FIG. 21, when d/p>about 0.5, the fractional bandwidth is less than about 5% even in a case where d/p is adjusted. On the other hand, in a case where d/p≤ about 0.5, when d/p is changed within this range, the fractional bandwidth of about 5% or more can be obtained, that is, the resonator having a high coupling coefficient can be provided. In addition, in a case where d/p is about 0.24 or less, the fractional bandwidth can be increased to about 7% or more. In addition, by adjusting d/p within this range, a resonator with a wider fractional bandwidth can be obtained, and a resonator with a higher coupling coefficient can be realized. Therefore, it is discovered that, by adjusting d/p to about 0.5 or less, it is possible to configure a resonator having a high coupling coefficient using the bulk wave in the thickness shear mode.

FIG. 22 is a plan view of the acoustic wave device using the bulk wave in the thickness shear mode. In an acoustic wave device 80, the pair of electrodes including the electrode 3 and electrode 4 are provided on the first main surface 2a of the piezoelectric layer 2. K in FIG. 22 is an intersecting width. As described above, in the acoustic wave device according to the present invention, the number of pairs of the electrodes may be one pair. Even in this case, when d/p is about 0.5 or less, it is possible to effectively excite the bulk wave in the thickness shear mode.

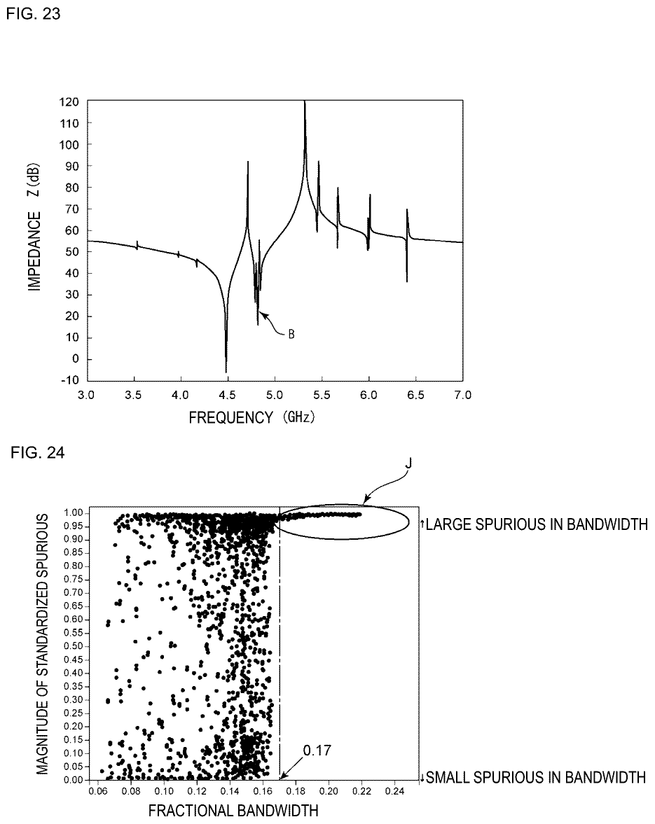

In the acoustic wave device 1, preferably, the metallization ratio MR of any adjacent electrodes 3 and 4 among the plurality of electrodes 3 and 4 to the excitation region C, which is the region in which the adjacent electrodes 3 and 4 overlap each other when viewed in the facing direction, satisfies, for example, MR≤about 1.75 (d/p)+0.075. In this case, the spurious response can be effectively reduced. This will be described with reference to FIGS. 23 and 24. FIG. 23 is a reference diagram illustrating an example of the resonance characteristics of the acoustic wave device 1. The spurious response indicated by an arrow B appears between the resonant frequency and the anti-resonant frequency. It should be noted that d/p=about 0.08 and the Euler angles of LiNbO₃ are (0°, 0°, 90°). Also, the metallization ratio MR is about 0.35.

The metallization ratio MR will be described with reference to FIG. 16B. In the electrode structure of FIG. 16B, it is assumed that, when focusing on the pair of electrodes 3 and 4, only the pair of electrodes 3 and 4 are provided. In this case, a portion surrounded by a one-dot chain line is the excitation region C. The excitation region C is, when the electrode 3 and the electrode 4 are viewed in the direction orthogonal or substantially orthogonal to the length direction of the electrodes 3 and 4, that is, in the facing direction, a region of the electrode 3 that overlaps the electrode 4, a region of the electrode 4 that overlaps the electrode 3, and a region between the electrode 3 and the electrode 4 in which the electrode 3 and the electrode 4 overlap each other. An area of the electrodes 3 and 4 in the excitation region C with respect to an area of the excitation region C is the metallization ratio MR. That is, the metallization ratio MR is a ratio of an area of the metallization portion to the area of the excitation region C.

In a case where the plurality of pairs of electrodes are provided, a ratio of the metallization portion included in the entire excitation region to a total area of the excitation region need only be MR.

FIG. 24 is a diagram illustrating a relationship between a fractional bandwidth and a phase rotation amount of an impedance of the spurious standardized at about 180 degrees as a magnitude of the spurious response in a case where a large number of acoustic wave resonators are configured according to the present example embodiment. The fractional bandwidth is adjusted by changing the film thickness of the piezoelectric layer and the dimensions of the electrodes. Moreover, FIG. 24 illustrates the results in a case where the piezoelectric layer made of the Z-cut LiNbO₃ is used, but the same or substantially the same tendency is obtained in a case where piezoelectric layers with other cut-angles are used.

In a region surrounded by an ellipse J in FIG. 24, the spurious response is as large as about 1.0. As is clear from FIG. 24, in a case where the fractional bandwidth exceeds about 0.17, that is, exceeds about 17%, a large spurious response with a spurious level of about 1 or more appears in a pass band even when the parameters constituting the fractional bandwidth are changed. That is, as in the resonance characteristics illustrated in FIG. 23, a large spurious response indicated by an arrow B appears within the band. Therefore, the fractional bandwidth is preferably, for example, about 17% or less. In this case, by adjusting the film thickness of the piezoelectric layer 2 and the dimensions of the electrodes 3 and 4, the spurious response can be reduced.

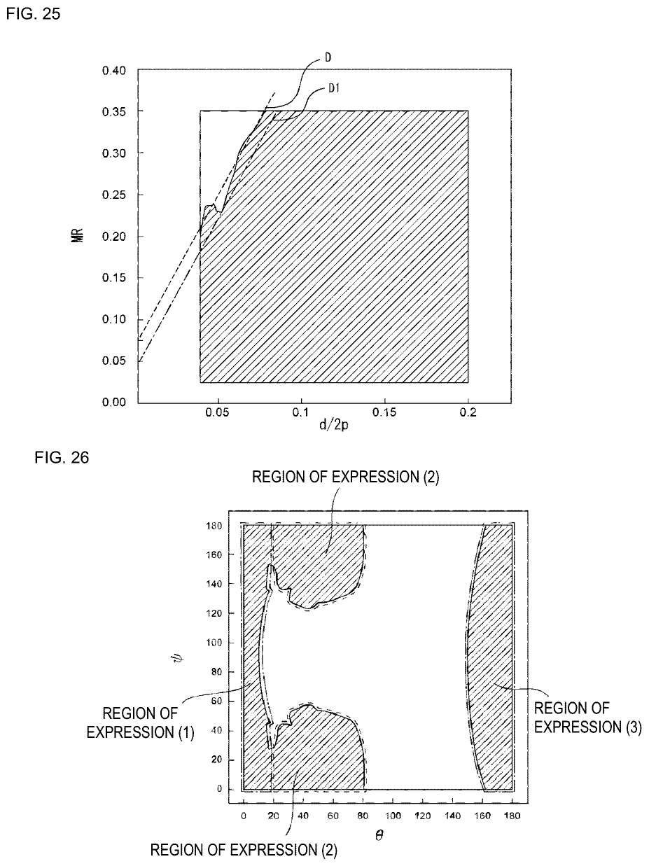

FIG. 25 is a diagram illustrating a relationship between d/2p, the metallization ratio MR, and the fractional bandwidth. Regarding the acoustic wave device described above, various acoustic wave devices having different d/2p and MR are configured, and the fractional bandwidth is measured. A hatched portion on a right side of a broken line D in FIG. 25 is a region in which the fractional bandwidth is about 17% or less. A boundary between the hatched region and a non-hatched region is expressed by MR=about 3.5(d/2p)+0.075. That is, MR=about 1.75 (d/p)+0.075. Therefore, preferably, for example, MR≤ about 1.75 (d/p)+0.075. In this case, it is easy to set the fractional bandwidth to about 17% or less. It is more preferable, for example, to have a region on a right side of MR=about 3.5 (d/2p)+0.05 indicated by a one-dot chain line D1 in FIG. 25. That is, in a case where MR≤ about 1.75 (d/p)+0.05, the fractional bandwidth can be reliably set to about 17% or less.

FIG. 26 is a diagram illustrating a map of the fractional bandwidth with respect to Euler angles (0°, θ, ψ) of LiNbO₃ in a case where d/p is infinitely close to 0. A hatched portion in FIG. 26 is a region in which the fractional bandwidth of at least about 5% or more is obtained, and in a case where a range of the region is approximated, the range is represented by Expressions (1), (2), and (3) below.

$$\\ \begin{matrix}( 0 ° \pm 10 ° , 0 ° to 20 ° , and ψ ) & Expression ( 1 )\end{matrix}$$

$$\\ \begin{matrix}( 0 ° \pm 10 ° , 20 ° to 80 ° , 0 ° to 60 ° {( 1 - {( θ - 50 )}^{2} / 900 )}^{1 / 2} ) or & Expression ( 2 )\end{matrix}$$

$$\\ ( 0 ° \pm 10 ° , 20 ° to 80 ° , [ 180 ° - 60 ° {( 1 - {( θ - 50 )}^{2} / 900 )}^{1 / 2} ] to 180 ° )$$

$$\\ \begin{matrix}( 0 ° \pm 10 ° , [ 180 ° - 30 ° {( 1 - {( ψ - 90 )}^{2} / 8100 )}^{1 / 2} ] to 180 ° , any ψ ) & Expression ( 3 )\end{matrix}$$

Therefore, in a case of the Euler angle range of Expression (1), Expression (2), or Expression (3) described above, the fractional bandwidth can be sufficiently widened, which is preferable. The same applies to a case where the piezoelectric layer 2 is the lithium tantalate layer.

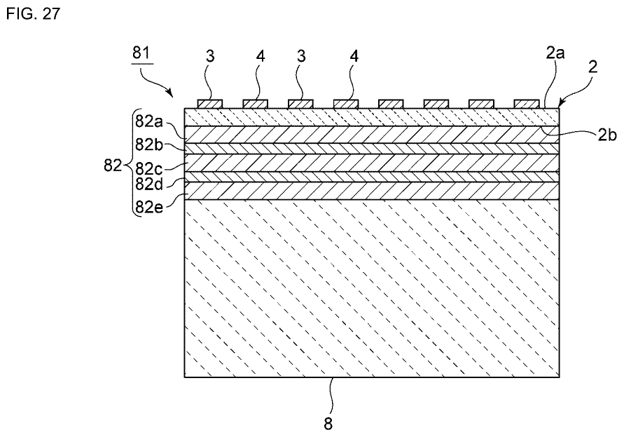

FIG. 27 is an elevational sectional view of the acoustic wave device including the acoustic multilayer film.

In an acoustic wave device 81, an acoustic multilayer film 82 is laminated on the second main surface 2b of the piezoelectric layer 2. The acoustic multilayer film 82 has a laminated structure including low acoustic impedance layers 82a, 82c, and 82e having a relatively low acoustic impedance and high acoustic impedance layers 82b and 82d having a relatively high acoustic impedance. In a case where the acoustic multilayer film 82 is used, the bulk wave in the thickness shear mode can be confined in the piezoelectric layer 2 without using the cavity portion 9 of the acoustic wave device 1. Also in the acoustic wave device 81, the resonance characteristics based on the bulk wave in the thickness shear mode can be obtained by setting d/p to about 0.5 or less, for example. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d should be disposed farther from the piezoelectric layer 2 than the low acoustic impedance layers 82a, 82c, and 82e.

The low acoustic impedance layers 82a, 82c, and 82e and the high acoustic impedance layers 82b and 82d can be made of an appropriate material as long as the above-described relationship of the acoustic impedance is satisfied. Examples of the material of the low acoustic impedance layers 82a, 82c, and 82e include silicon oxide and silicon oxynitride. In addition, examples of the material of the high acoustic impedance layers 82b and 82d include alumina, silicon nitride, and metal.

In the acoustic wave devices according to the first to sixth example embodiments and each of the modified examples, for example, the acoustic multilayer film 82 illustrated in FIG. 27 may be provided as the acoustic reflection film between the support and the piezoelectric layer. Specifically, the support and the piezoelectric layer may be disposed such that at least a portion of the support and at least a portion of the piezoelectric layer face each other with the acoustic multilayer film 82 interposed therebetween. In this case, in the acoustic multilayer film 82, the low acoustic impedance layer and the high acoustic impedance layer need only be alternately laminated. The acoustic multilayer film 82 may be the acoustic reflection portion in the acoustic wave device.

In the acoustic wave devices according to the first to sixth example embodiments and each of the modified examples that use the bulk wave in the thickness shear mode, as described above, d/p is preferably, for example, about 0.5 or less, and more preferably about 0.24 or less. As a result, better resonance characteristics can be obtained. Further, in the intersecting regions in the acoustic wave devices according to the first to sixth example embodiments and each of the modified examples that use the bulk wave in the thickness shear mode, as described above, preferably, for example, MR≤ about 1.75 (d/p)+0.075 is satisfied. In this case, it is possible to more reliably reduce or prevent the spurious response.

It is preferable that the piezoelectric layers in the acoustic wave devices according to the first to sixth example embodiments and each of the modified examples that use the bulk wave in the thickness shear mode is, for example, a lithium niobate layer or a lithium tantalate layer. In addition, it is preferable that the Euler angles (φ, θ, ψ) of lithium niobate or lithium tantalate of the piezoelectric layer are in the range of Expression (1), Expression (2), or Expression (3) described above. In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on the support and including lithium niobate or lithium tantalate; and
an interdigital transducer (IDT) electrode on the piezoelectric layer and including a pair of busbars and a plurality of electrode fingers; wherein
an acoustic reflection portion is provided at a position overlapping at least a portion of the IDT electrode in plan view viewed in a laminating direction of the support and the piezoelectric layer;
d/p is about 0.5 or less, where d is a thickness of the piezoelectric layer and p is a center-to-center distance between the electrode fingers adjacent to each other;
some electrode fingers among the plurality of electrode fingers are connected to one of the pair of busbars of the IDT electrode, remaining electrode fingers among the plurality of electrode fingers are connected to another of the pair of busbars, and the some of the electrode fingers connected to the one of the pair of busbars and the remaining of the electrode fingers connected to the another of the pair of busbars are interdigitated with each other;
where a direction in which the adjacent electrode fingers face each other is an electrode finger facing direction, a region in which the adjacent electrode fingers overlap each other when viewed in the electrode finger facing direction is an intersecting region, and where a direction in which the plurality of electrode fingers extend is an electrode finger extending direction, the intersecting region includes a central region and a pair of edge regions sandwiching the central region in the electrode finger extending direction, and edge regions located between the intersecting region and the pair of busbars; and
at least one mass addition film is provided in at least one of the pair of edge regions or the pair of gap regions, and where any two points, in the electrode finger facing direction, of a portion in which the mass addition film is located are a first point and a second point, thicknesses of the mass addition film at at least a pair of the first point and the second point are different from each other.

2. The acoustic wave device according to claim 1, wherein the at least one mass addition film is provided only in each of the edge regions.

3. The acoustic wave device according to claim 1, wherein the at least one mass addition film is provided only in each of the gap regions.

4. The acoustic wave device according to claim 1, wherein the at least one mass addition film is provided over one of the pair of edge regions and one of the pair of gap regions and over another of the pair of edge regions and another of the pair of gap regions.

5. The acoustic wave device according to claim 1, wherein each of the plurality of electrode fingers includes a first surface and a second surface facing each other, the second surface is on a piezoelectric layer side, and the at least one mass addition film is provided on the first surfaces of the plurality of electrode fingers.

6. The acoustic wave device according to claim 1, wherein each of the plurality of electrode fingers includes a first surface and a second surface facing each other, the second surface is on a piezoelectric layer side, and the at least one mass addition film is provided between the second surfaces of the plurality of electrode fingers and the piezoelectric layer.

7. The acoustic wave device according to claim 1, wherein a protective film is provided on the piezoelectric layer to cover the IDT electrode, and the at least one mass addition film is provided on the protective film.

8. The acoustic wave device according to claim 1, wherein the mass addition film is provided only in a region overlapping the plurality of electrode fingers in plan view.

9. The acoustic wave device according to claim 1, wherein the mass addition film is continuously provided in a region overlapping the plurality of electrode fingers and overlapping a region between the electrode fingers in plan view.

10. The acoustic wave device according to claim 7, wherein the mass addition film is made of metal.

11. The acoustic wave device according to claim 1, wherein the mass addition film includes at least one of silicon oxide, tungsten oxide, niobium oxide, tantalum oxide, or hafnium oxide.

12. The acoustic wave device according to claim 1, wherein the acoustic reflection portion is a cavity portion, and a portion of the support and a portion of the piezoelectric layer face each other with the cavity portion interposed therebetween.

13. The acoustic wave device according to claim 1, wherein
the acoustic reflection portion includes an acoustic reflection film including a high acoustic impedance layer having a relatively high acoustic impedance and a low acoustic impedance layer having a relatively low acoustic impedance; and
at least a portion of the support and at least a portion of the piezoelectric layer face each other with the acoustic reflection film interposed therebetween.

14. The acoustic wave device according to claim 1, wherein d/p is about 0.24 or less.

15. The acoustic wave device according to claim 1, wherein an excitation region is a region in which the adjacent electrode fingers overlap each other when viewed in the electrode finger facing direction and is a region between centers of the adjacent electrode fingers; and
MR≤about 1.75 (d/p)+0.075 is satisfied, where MR is a metallization ratio of the plurality of electrode fingers to the excitation region.

16. The acoustic wave device according to claim 1, wherein
Euler angles (φ, θ, ψ) of the lithium niobate layer or the lithium tantalate layer as the piezoelectric layer are in a range of Expression (1), Expression (2), or Expression (3):
$$\\ \begin{matrix}( 0 ° \pm 10 ° , 0 ° to 20 ° , and ψ ) ; & Expression ( 1 )\end{matrix}$$
$$\\ \begin{matrix}( 0 ° \pm 10 ° , 20 ° to 80 ° , 0 ° to 60 ° {( 1 - {( θ - 50 )}^{2} / 900 )}^{1 / 2} ) or & Expression ( 2 )\end{matrix}$$
$$\\ ( 0 ° \pm 10 ° , 20 ° to 80 ° , [ 180 ° - 60 ° {( 1 - {( θ - 50 )}^{2} / 900 )}^{1 / 2} ] to 180 ° ) ; and$$
$$\\ \begin{matrix}( 0 ° \pm 10 ° , [ 180 ° - 30 ° {( 1 - {( ψ - 90 )}^{2} / 8100 )}^{1 / 2} ] to 180 ° , any ψ ) . & Expression ( 3 )\end{matrix}$$

17. The acoustic wave device according to claim 1, wherein an insulating layer is provided between the support substrate and the piezoelectric layer.

18. The acoustic wave device according to claim 1, wherein the support substrate includes silicon or aluminum oxide.

19. The acoustic wave device according to claim 1, wherein the mass addition film includes silicon oxide, tungsten oxide, niobium oxide, tantalum oxide, or hafnium oxide.

20. The acoustic wave device according to claim 1, wherein the mass addition film has a strip shape.
